(19) United States
(12) Patent Application Publication
(10) Pub. No.: US 2023/0335420 A1
(43) Pub. Date: Oct. 19, 2023

(54) METHOD FOR MANUFACTURING SEMICONDUCTOR DEVICE AND SEMICONDUCTOR MANUFACTURING APPARATUS

(71) Applicant: Mitsubishi Electric Corporation, Tokyo (JP)

(72) Inventors: Kazuaki MIKAMI, Tokyo (JP); Tomohiro ISHII, Tokyo (JP); Katsumi NAKAMURA, Tokyo (JP); Kazunori KANADA, Fukuoka (JP)

(73) Assignee: Mitsubishi Electric Corporation, Tokyo (JP)

(21) Appl. No.: 18/177,058

(22) Filed: Mar. 1, 2023

(30) Foreign Application Priority Data
Apr. 19, 2022 (JP) 2022-068615

(51) Int. Cl. H01L 21/67; H01L 21/265; H01L 29/66; H01L 21/66

(52) U.S. Cl. CPC H01L 21/67115; H01L 21/26513; H01L 29/66348; H01L 22/20; H01L 21/67288; H01L 21/304

(57) ABSTRACT

A crack generated on a main surface of a substrate is detected, and the main surface of the substrate is scanned with the laser light in order that a time integral of a light amount of laser light for annealing with which a unit area in a crack region including the detected crack is irradiated is smaller than a time integral of a light amount of the laser light with which a unit area in a region different from the crack region is irradiated, to perform laser annealing treatment on the substrate.

### FIELD OF THE INVENTION

The present disclosure relates to a method for manufacturing a semiconductor device and a semiconductor manufacturing apparatus.

### DESCRIPTION OF THE BACKGROUND ART

The laser annealing step being one of the manufacturing steps of the semiconductor device is a step of locally heating the semiconductor substrate using a laser to activate, for example, the semiconductor layer. Currently, thinning of a semiconductor substrate progresses in order to meet a market demand for low loss.

Japanese Patent Application Laid-Open No. 2014-11358 discloses a technique for laser dicing a substrate to be processed. In Japanese Patent Application Laid-Open No. 2014-11358, in order to avoid repetition of laser irradiation, laser light is blocked when laser light passes through a region irradiated once.

Since the substrate is thinned by the thinning step, when a crack is generated on one main surface of the substrate, the crack is likely to extend to the other main surface of the substrate. When a crack on one main surface is irradiated with laser light by laser annealing, the laser light is likely to reach the other main surface of the substrate, and the other main surface of the substrate is unnecessarily heated. By this heating, for example, a problem such as adhesion may occur between a stage that supports the other main surface of the substrate and the substrate.

In order to solve such a problem, it is conceivable to discard in advance a substrate in which a crack has occurred and to perform laser annealing treatment only on a substrate in which no crack has occurred. However, if the substrate is discarded, the yield rate is reduced.

### SUMMARY

An object of the present disclosure is to provide a method and an apparatus for manufacturing a semiconductor device capable of performing laser annealing treatment while suppressing a problem even on a substrate in which a crack occurs.

A method for manufacturing a semiconductor device according to the present disclosure is a method for manufacturing a semiconductor device, the method including: detecting a crack generated on a main surface of a substrate; and scanning the main surface of the substrate with the laser light in order that a time integral of a light amount of laser light for annealing with which a unit area in a crack region including the detected crack is irradiated is smaller than a time integral of a light amount of the laser light with which a unit area in a region different from the crack region is irradiated, to perform laser annealing treatment on the substrate.

A semiconductor manufacturing apparatus of the present disclosure includes an inspection unit, a stage, an optical unit, a scanning section, and a control unit.

The inspection unit is configured to detect a crack generated on a main surface of a substrate.

The stage is configured to hold the substrate.

The optical unit is configured to irradiate the substrate held by the stage with laser light for annealing.

The scanning section is configured to scan the substrate with the laser light.

A control unit is configured to control the optical unit and the scanning section so that the main surface of the substrate is scanned with the laser light in order that a time integral of a light amount of the laser light with which a unit area in a crack region including the crack detected by the inspection unit is irradiated is smaller than a time integral of a light amount of the laser light with which a unit area in a region different from the crack region is irradiated, to perform laser annealing treatment on the substrate.

According to the present disclosure, it is possible to perform laser annealing treatment even on a substrate in which a crack has occurred while suppressing the problem.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically showing an example of a configuration of a semiconductor manufacturing apparatus;

FIG. 2 is a plan view schematically showing an example of a configuration of a semiconductor substrate;

FIG. 3 is a side view schematically showing an example of a configuration of a laser annealing unit according to a first preferred embodiment;

FIG. 4 is a block diagram schematically showing an example of an electrical configuration of the semiconductor manufacturing apparatus;

FIG. 5 is a view schematically showing an example of a track of movement of a beam being an irradiation region on the semiconductor substrate of the laser light;

FIG. 6 is a diagram for illustrating an irradiation map according to the first preferred embodiment;

FIG. 7 is an enlarged view of a part of the irradiation map in FIG. 6;

FIG. 8 is a flowchart showing an example of a method for manufacturing a semiconductor device;

FIGS. 9A to 9H are cross-sectional views schematically showing an example of a configuration of the semiconductor substrate in each step;

FIG. 10 is a flowchart showing a specific example of a second main surface side laser annealing step;

FIG. 11 is a diagram showing an example of a temporal change in the open/close state of a laser opening and closing apparatus after rewriting;

FIG. 12 is an enlarged view showing another example of the irradiation map according to the first preferred embodiment;

FIG. 13 is a side view showing an example of a configuration of a laser annealing unit according to a second preferred embodiment;

FIG. 14 is a side view showing an example of a configuration of a laser annealing unit according to a third preferred embodiment;

FIG. 15 is a diagram for illustrating the irradiation map according to the third preferred embodiment;

FIG. 16 is an enlarged view of a part of the irradiation map in FIG. 15;

FIG. 17 is a graph showing an example of a temporal change in a scanning speed and a pitch speed; and

FIG. 18 is an enlarged view showing another example of the irradiation map according to the third preferred embodiment.

### DESCRIPTION OF THE PREFERRED EMBODIMENTS

### First Preferred Embodiment

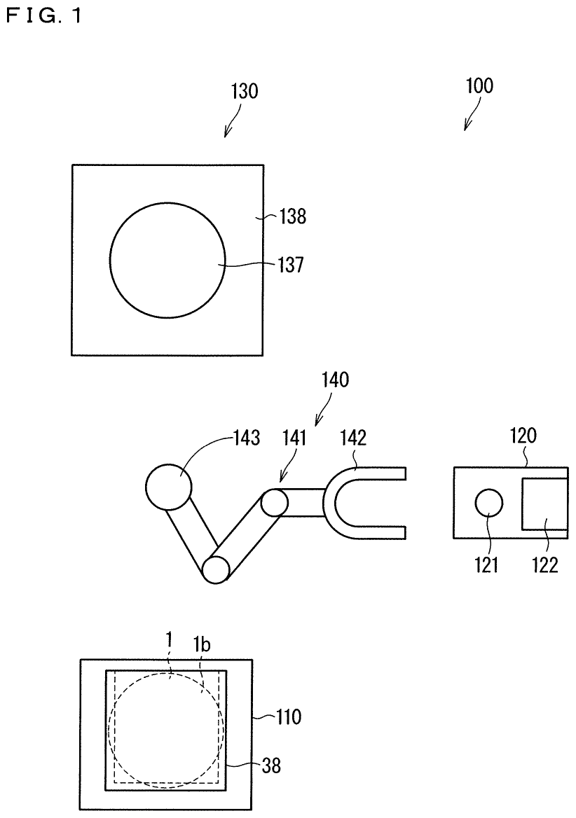

FIG. 1 is a plan view schematically showing an example of a configuration of a semiconductor manufacturing apparatus 100 according to a first preferred embodiment. A semiconductor substrate 1 is carried into the semiconductor manufacturing apparatus 100. The semiconductor substrate 1 has, for example, a disk shape.

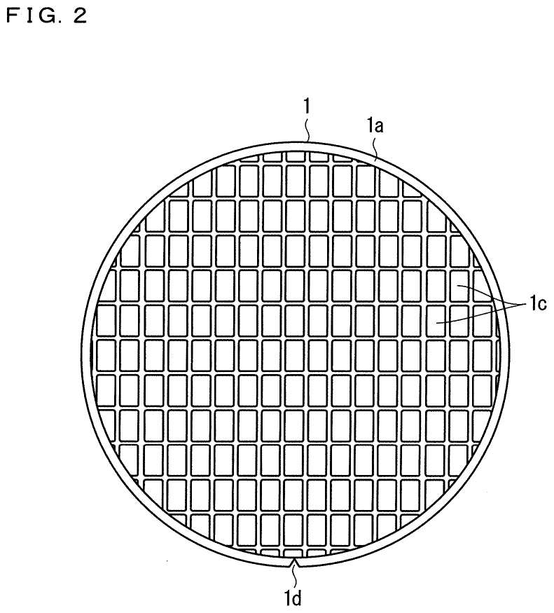

FIG. 2 is a plan view schematically showing an example of a configuration of the semiconductor substrate 1. Hereinafter, one main surface of the semiconductor substrate 1 is also referred to as a first main surface 1a, and a main surface opposite to the first main surface 1a is also referred to as a second main surface 1b. In plan view, a plurality of semiconductor device regions 1c are formed on the semiconductor substrate 1. Various semiconductor layers, insulating layers, and electrodes are formed in each semiconductor device region 1c, and a semiconductor device is manufactured. The semiconductor substrate 1 in the middle of manufacture is carried into the semiconductor manufacturing apparatus 100, and more specifically, the semiconductor substrate 1 in a state where an impurity implantation layer is formed in each semiconductor device region 1c is carried into the semiconductor manufacturing apparatus 100.

The semiconductor manufacturing apparatus 100 is a laser annealing apparatus that performs laser annealing treatment on the semiconductor substrate 1. The laser annealing treatment is a treatment in which the semiconductor substrate 1 is heated by irradiating the semiconductor substrate 1 with laser light, and the impurity injection layer of the semiconductor substrate 1 is electrically activated by this heating. By this laser annealing treatment, the impurity implantation layer of the semiconductor substrate 1 becomes a semiconductor layer having a conductivity type corresponding to the impurity.

In the example in FIG. 1, the semiconductor manufacturing apparatus 100 includes a load port 110, an inspection unit 120, a laser annealing unit 130, and a transport unit 140. The load port 110 is an interface section for carrying in and out the semiconductor substrate 1 from and to the outside. Here, a cassette 38 storing a plurality of semiconductor substrates 1 is carried into and out of the load port 110. It should be noted that although one load port 110 is shown in the example in FIG. 1, a plurality of load ports 110 may be provided.

The transport unit 140 takes out the untreated semiconductor substrate 1 from the cassette 38 and transports the semiconductor substrate 1 to the inspection unit 120. The inspection unit 120 inspects the presence or absence of a crack in the semiconductor substrate 1 as described below. The transport unit 140 takes out the inspected semiconductor substrate 1 from the inspection unit 120, and transports the semiconductor substrate 1 to the laser annealing unit 130. The laser annealing unit 130 causes laser light to scan in the semiconductor substrate 1 according to the inspection result of the inspection unit 120 to perform laser annealing treatment on the semiconductor substrate 1. The laser annealing treatment according to the inspection result will be described in detail below. The transport unit 140 takes out the semiconductor substrate 1 on which the laser annealing treatment has been performed from the laser annealing unit 130, and transports the semiconductor substrate 1 to the cassette 38.

The transport unit 140 sequentially takes out the untreated semiconductor substrates 1 from the cassette 38 and transports the untreated semiconductor substrates 1 along the transport path, whereby the treated semiconductor substrates 1 are sequentially stored in the cassette 38. When all the semiconductor substrates 1 are treated, the cassette 38 is carried out from the load port 110 to the outside.

<Transport Unit 140>

The transport unit 140 includes, for example, an articulated arm 141, a hand 142, and an elevating section 143. A hand 142 is attached to a tip of the articulated arm 141, and a base end of the articulated arm 141 is attached to the elevating section 143. The articulated arm 141 horizontally moves the hand 142 by driving the joint section. The elevating section 143 integrally elevates the articulated arm 141 and the hand 142 by elevating the articulated arm 141. The hand 142 may be a hand of any of a scoop up system and a Bernoulli system.

<Inspection unit 120>

In the example in FIG. 1, the inspection unit 120 includes an aligner 121 and a sensor section 122. The aligner 121 includes, for example, a holding mechanism that horizontally holds the semiconductor substrate 1 and a rotation mechanism that rotates the semiconductor substrate 1 held by the holding mechanism. The holding mechanism holds the semiconductor substrate 1 by various systems such as a vacuum chuck, an electrostatic chuck, and a mechanical chuck. Here, the holding mechanism holds the semiconductor substrate 1 with the second main surface 1b in an attitude of being directed vertically upward. The rotation mechanism includes, for example, a motor, and rotates the holding mechanism around a specified rotation axis line. The specified rotation axis line is an axis line that passes through the center of the semiconductor substrate 1 in a state held by the holding mechanism and is parallel to the vertical direction. When the rotation mechanism rotates the holding mechanism, the semiconductor substrate 1 held by the holding mechanism also rotates around the rotation axis line. As shown in FIG. 2, a notch 1d is formed in the semiconductor substrate 1, and the aligner 121 rotates the semiconductor substrate 1 so that the notch 1d is at a specified rotational position.

The sensor section 122 includes a sensor for detecting a crack that may occur in the semiconductor substrate 1. The term “crack” here includes a crack and a fissure generated on the second main surface 1b of the semiconductor substrate 1. The crack may reach the first main surface 1a of the semiconductor substrate 1 or may reach the circumferential edge of the semiconductor substrate 1. The crack reaching the first main surface 1a may also be referred to as a through crack. The sensor section 22 detects the presence or absence of a crack in the semiconductor substrate 1, and also detects the position and shape of the crack when the crack is generated.

The sensor of the sensor section 122 is, for example, a sensor of an image inspection system or a laser inspection system. In the former case, the sensor is, for example, an image sensor including light receiving elements arranged two-dimensionally, and images the second main surface 1b of the semiconductor substrate 1. The sensor section 122 detects a crack based on a captured image obtained by imaging the semiconductor substrate 1. In the latter case, the sensor includes, for example, a light emitting section that irradiates the second main surface 1b of the semiconductor substrate 1 with the inspection light, and a light receiving section that receives the inspection light reflected from the second main surface 1b of the semiconductor substrate 1. The sensor section 122 detects a crack based on the amount of received light measured by the light receiving section.

<Laser Annealing Unit 130>

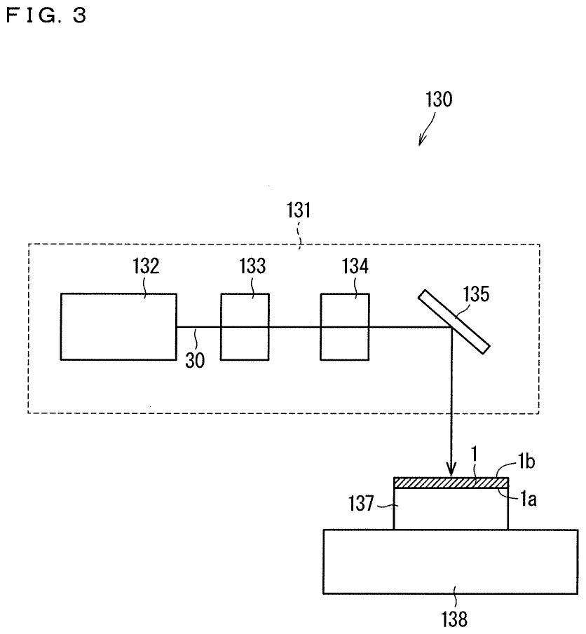

FIG. 3 is a side view schematically showing an example of a configuration of the laser annealing unit 130 according to the first preferred embodiment. The laser annealing unit 130 includes an optical unit 131, a stage 137, and a scanning section 138.

The stage 137 horizontally holds the semiconductor substrate 1. Here, the stage 137 holds the semiconductor substrate 1 with the second main surface 1b in an attitude of being directed vertically upward. As a chuck system of the stage 137, any of a vacuum chuck, an electrostatic chuck, and a mechanical chuck may be adopted as long as the flatness of the second main surface 1b of the semiconductor substrate 1 can be secured.

When a vacuum chuck is employed, a plurality of suction holes are formed on the upper surface of the stage 137. A negative pressure is formed in the suction hole by a suction mechanism (not shown), whereby the semiconductor substrate 1 is sucked to the stage 137. In order to suppress the defocus influence in the suction hole section, the diameter of each suction hole is desirably 1 mm or less. It should be noted that the stage 137 may be formed of a porous material. Also in this case, the pore diameter (corresponding to the suction hole) of the stage 137 is 1 mm or less. A chuck system of this stage 137 is also referred to as a porous chuck.

The optical unit 131 irradiates the semiconductor substrate 1 held by the stage 137 with laser light 30 for annealing. For example, the optical unit 131 includes a laser oscillator 132, a transmittance adjustment mechanism 133 such as an attenuator, a laser opening and closing apparatus 134, and a mirror 135. It should be noted that although the optical unit 131 further includes a uniform optical system for uniformizing the light amount distribution of light, such as a homogenizer, and a condenser lens for condensing the laser light 30, illustration of these components are omitted in FIG. 3.

The laser oscillator 132 emits laser light 30. The laser light 30 from the laser oscillator 132 is incident on the transmittance adjustment mechanism 133. The transmittance adjustment mechanism 133 adjusts the amplitude of the laser light 30 by adjusting its own transmittance. The laser light 30 transmitted through the transmittance adjustment mechanism 133 is incident on the laser opening and closing apparatus 134.

The laser opening and closing apparatus 134 switches between an open state in which the laser light 30 is passed and a closed state in which the laser light 30 is blocked. For example, the laser opening and closing apparatus 134 includes a plate member having an opening and a moving mechanism that moves the plate member. The moving mechanism includes, for example, a drive source such as a motor, and moves the plate member between the open position and the closed position. The open position is the position of the plate member when the laser light 30 passes through the opening, and the closed position is the position of the plate member when the laser light 30 is blocked by the plate member.

The laser light 30 having passed through the laser opening and closing apparatus 134 is incident on the mirror 135. The mirror 135 reflects the laser light 30 toward the semiconductor substrate 1 on the stage 137. The laser light 30 reflected by the mirror 135 is applied to the semiconductor substrate 1.

The scanning section 138 scans the semiconductor substrate 1 with the laser light 30. For example, the scanning section 138 moves the stage 137 two-dimensionally along the horizontal direction with respect to the optical unit 131. The movement of the stage 137 causes the laser light 30 to move on the semiconductor substrate 1. It should be noted that the scanning section 138 does not necessarily need to move the stage 137, and the optical unit 131 may be moved with respect to the stage 137. Alternatively, the scanning section 138 may include a galvanometer mirror and an fθ lens.

<Electrical Configuration of Semiconductor Manufacturing Apparatus 100>

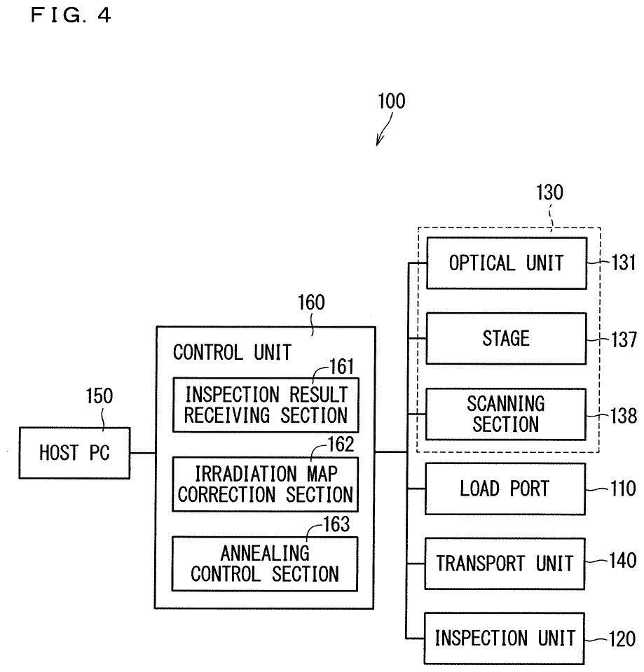

FIG. 4 is a block diagram schematically showing an example of an electrical configuration of the semiconductor manufacturing apparatus 100. The semiconductor manufacturing apparatus 100 further includes, for example, a host personal computer (PC) 150 and a control unit 160. The host PC 150 is electrically connected to the control unit 160 and issues various instructions to the control unit 160. The control unit 160 is electrically connected to and controls the load port 110, the inspection unit 120, the laser annealing unit 130, and the transport unit 140.

The control unit 160 is an electronic circuit, and includes, for example, a processing circuit such as a central processing unit (CPU), a transitory storage section such as a random access memory (RAM), and a non-transitory storage section such as a read only memory (ROM). A program is stored in the non-transitory storage section, and the processing circuit operates according to the program, whereby the control unit 160 can perform a specified operation. It should be noted that some or all of the functions of the control unit 160 are not necessarily needed to be implemented by software, and may be implemented by dedicated hardware such as a logic circuit.

In addition, since the host PC 150 also includes a control unit similar to the control unit 160, it can be grasped that the whole of the host PC 150 and the control unit 160 constitutes one control unit.

Here, the scanning control of the laser light 30 by the control unit 160 will be first summarized, and then a detailed operation example will be described.

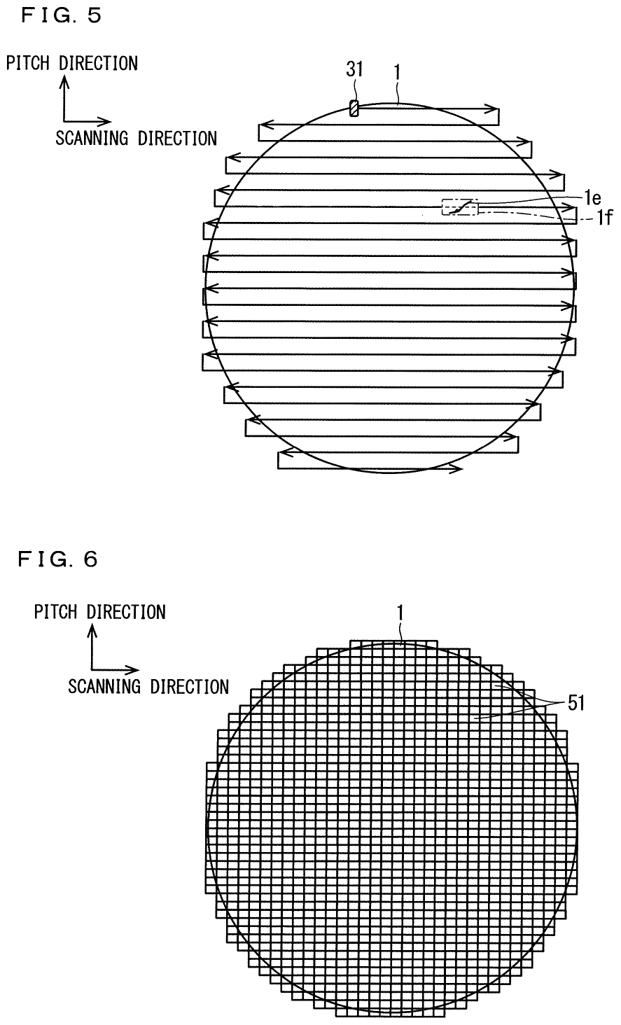

FIG. 5 is a view schematically showing an example of a track of movement of a beam 31 being an irradiation region (that is, spot) on the semiconductor substrate 1 of the laser light 30. In FIG. 5, the track of the movement of the beam 31 is mainly indicated by a solid arrow. The beam 31 moves across the semiconductor substrate 1 by moving on a scanning line along the scanning direction, and moves to the next scanning line along a pitch direction orthogonal to the scanning direction on the outer peripheral side from the semiconductor substrate 1. By the beam 31 sequentially moving along all the scanning lines, the entire semiconductor substrate 1 is scanned.

In the example in FIG. 5, a crack 1e is formed in the semiconductor substrate 1. The crack 1e is detected by the inspection unit 120, and an inspection result signal including the position and shape of the crack 1e is output from the inspection unit 120 to the control unit 160.

As described below, the control unit 160 controls the laser annealing unit 130 so that the laser annealing unit 130 scans the semiconductor substrate 1 with the laser light 30 to perform laser annealing treatment on the semiconductor substrate 1. Specifically, the control unit 160 controls the laser annealing unit 130 so that the time integral of the light amount of the laser light 30 applied to the unit area in the crack region 1f including the crack 1e is smaller than the time integral of the light amount of the laser light 30 applied to the unit area in a region different from the crack region 1f. As a more specific example, the laser annealing unit 130 causes the beam 31 to disappear when the beam 31 passes through the crack 1e. For example, the control unit 160 operates the laser opening and closing apparatus 134 and the scanning section 138 in synchronization, and causes the laser opening and closing apparatus 134 to block the laser light 30 in a period in which the beam 31 passes through the crack region 1f.

Accordingly, irradiation of the crack 1e with the laser light 30 (that is, the beam 31) can be substantially avoided, and the amount of heat applied to the crack region 1f can be reduced. Therefore, it is possible to suppress a problem caused by irradiation of the crack 1e with the laser light 30. Specific examples of the problem will also be described below.

<Example of Functional Section of Control Unit 160>

Next, an example of a specific functional section of the control unit 160 for implementing the above control will be described. In the example in FIG. 4, the control unit 160 includes an inspection result receiving section 161, an irradiation map correction section 162, and an annealing control section 163.

The inspection result receiving section 161 receives an inspection result signal indicating an inspection result by the inspection unit 120 from the inspection unit 120. The inspection result signal includes, for example, information indicating the presence or absence of the crack 1e and information indicating the position and shape of the crack 1e on the semiconductor substrate 1. The position and shape of the crack 1e can be represented using coordinates in a virtual coordinate system set on the second main surface 1b of the semiconductor substrate 1.

The irradiation map correction section 162 corrects irradiation map information indicating the irradiation map on the semiconductor substrate 1 to be irradiated with the laser light 30 based on the inspection result signal of the inspection unit 120. Here, first, the irradiation map will be described.

FIG. 6 is a diagram for illustrating the irradiation map according to the first preferred embodiment. The irradiation map includes a plurality of components 51 virtually arranged on the semiconductor substrate 1 in plan view. The plurality of components 51 have a rectangular shape and are adjacent to each other in plan view. The plurality of components 51 are arranged in a matrix shape so as to cover the entire surface of the semiconductor substrate 1 with the scanning direction as the row direction and the pitch direction as the column direction.

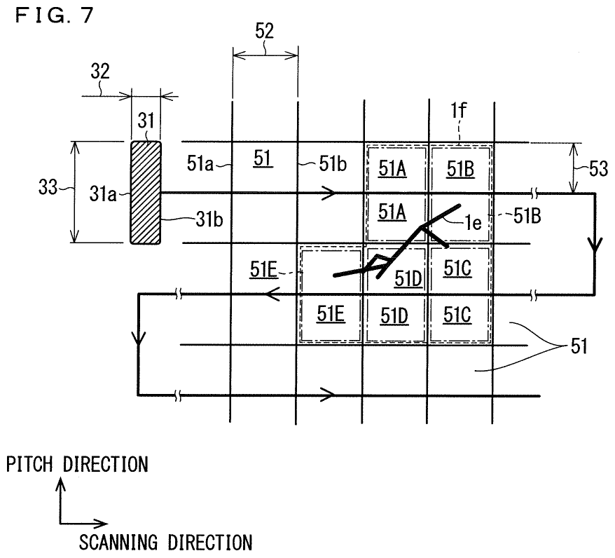

FIG. 7 is an enlarged view of a part of the irradiation map in FIG. 6. In the example in FIG. 7, the beam 31 is also shown. Here, as an example, a beam 31 formed by a homogeneous optical system is shown. In the example in FIG. 7, the beam 31 has a rectangular shape in which the scanning direction of the beam 31 is the lateral direction. Conversely, the optical unit 131 forms the shape of the laser light 30 so that the shape in the cross section perpendicular to the traveling direction of the laser light 30 is similar to the shape of the beam 31 in FIG. 7.

The size of the component 51 is preset based on the beam 31 and registered in the host PC 150. The size of each component 51 is defined by a width 52 and a width 53. The width 52 is a width along the scanning direction, and the width 53 is a width along the pitch direction. The width 53 of the component 51 is set based on the beam width 33 (specifically, the width along the pitch direction) of the beam 31. As a specific example, the width 53 of the component 51 is set to an integral submultiple (here, one-half) of the beam width 33. In this case, the beam 31 moves along the scanning direction, whereby the components 51 for two rows are irradiated with the laser light 30. That is, one scanning line includes components 51 for two rows.

The width 52 of the component 51 is set to be at least equal to or larger than the beam width 32 (specifically, the width along the scanning direction) of the beam 31, and may be set, for example, as described next in the present preferred embodiment. That is, the width 52 of the component 51 is set so that the laser opening and closing apparatus 134 can complete the switching operation of the open or closed state within the passing period during which the beam 31 passes through one component 51 in the scanning direction. The term “passing period” here specifically refers to the following period. Here, a case where the beam 31 moves from left to right will be described as an example. In this case, the left end 31a of the beam 31 corresponds to the rear end in the moving direction, and the right end 31b of the beam 31 corresponds to the front end. Similarly, the left end 51a of the component 51 corresponds to the rear end, and the right end 51b corresponds to the front end. The passing period is a period from a time point when the rear end 31a of the beam 31 reaches the rear end 51a of the component 51 to a time point when the front end 31b of the beam 31 reaches the front end 51b of the component 51.

For example, assume that the beam width 32 is 0.2 mm, the moving speed of the beam 31 is 200 mm/sec, and the opening and closing time required for the switching operation of the laser opening and closing apparatus 134 is 0.5 msec. In this case, the width 52 of the component 51 is desirably defined to be equal to or larger than the sum (=1.2 mm) of the beam width 32 and the movement amount (=1.0 mm) of the beam 31 during the switching operation of the laser opening and closing apparatus 134. Accordingly, the laser opening and closing apparatus 134 can cause the beam 31 to disappear or revive during the passing period during which the beam 31 passes through one component 51.

More preferably, the width 52 of the component 51 is set so that the laser opening and closing apparatus 134 can return the state to the open state again through from the open state to the closed state within the passing period. In other words, the width 52 of the component 51 is desirably defined to be equal to or larger than the sum (=2.2 mm) of the beam width 32 and the movement amount (=2.0 mm) of the beam 31 during the two times of switching operation of the laser opening and closing apparatus 134. According to this, the laser opening and closing apparatus 134 can cause the beam 31 to disappear once and then revive during the passing period during which the beam 31 passes through one component 51.

The irradiation map information includes, for example, information on the light amount of the beam 31 with which each component 51 is irradiated. In the irradiation map information, initially, the irradiation map is set so that all the components 51 are irradiated with the beam 31 with a specified light amount. Therefore, in the scanning control based on the initial irradiation map information, the operation information on the optical unit 131 and the scanning section 138 is determined so that all the components 51 are irradiated with the beam 31 with a specified light amount. For example, the operation information may be determined so that the laser opening and closing apparatus 134 always keeps the open state during scanning of the laser light 30 and the scanning section 138 causes the beam 31 to pass through all the components 51 (that is, all scanning lines).

The irradiation map correction section 162 corrects the irradiation map information based on the position and the shape of the crack 1e included in the inspection result signal from the inspection unit 120. In the example in FIG. 7, the crack 1e is formed across the five components 51. The crack region 1f is a region including the crack 1e and having the component 51 constituting the scanning line of each row as one minimum unit. Here, since the scanning line includes the components 51 for two rows, two components 51 arranged in the pitch direction constitute one minimum unit. The irradiation map correction section 162 corrects the irradiation map information so that the time integral of the light amount per unit area in the crack region 1f is smaller than the time integral of the light amount per unit area in the component 51 different from the crack region 1f. For example, the irradiation map information is corrected so that the beam 31 disappears in the crack region 1f.

The host PC 150 rewrites the operation information on the optical unit 131 and the scanning section 138 registered in itself based on the corrected irradiation map information, and transfers the corrected operation information to the control unit 160. It should be noted that the control unit 160 may also rewrite the operation information.

The annealing control section 163 synchronously controls the optical unit 131 and the scanning section 138 based on the corrected operation information. Specifically, for example, the annealing control section 163 causes the laser opening and closing apparatus 134 to block the laser light 30 in a period in which the beam 31 passes through the crack region 1f.

<Method for Manufacturing Semiconductor Device>

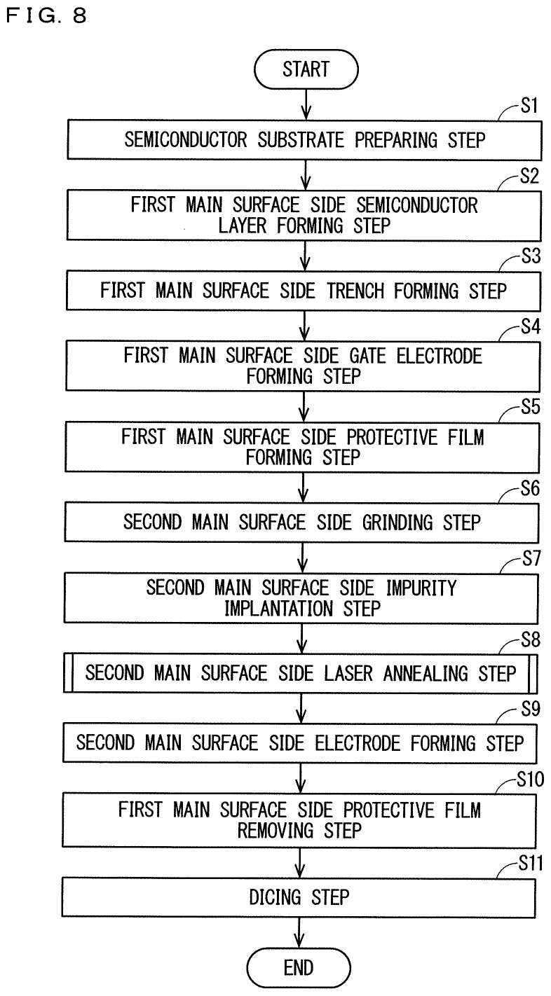

Next, with a method for manufacturing a semiconductor device of manufacturing a reverse conducting insulated gate bipolar transistor (RC-IGBT) as an example, a method for manufacturing a semiconductor device of the present preferred embodiment will be described more specifically. In addition, in the description of the method for manufacturing the semiconductor device, the operation of the semiconductor manufacturing apparatus 100 will be described. FIG. 8 is a flowchart showing an example of a method for manufacturing a semiconductor device.

In the following description of the method for manufacturing the semiconductor device, the method for manufacturing the active region of the RC-IGBT is described, and the method for manufacturing the termination region, the gate signal receiving region, and the like is omitted.

In the method for manufacturing a semiconductor device of each preferred embodiment, a semiconductor device is manufactured with a plurality of semiconductor substrates 1 as one group. As shown in FIG. 2, in each of the plurality of semiconductor substrates 1, a semiconductor device is formed in at least one semiconductor device region 1c.

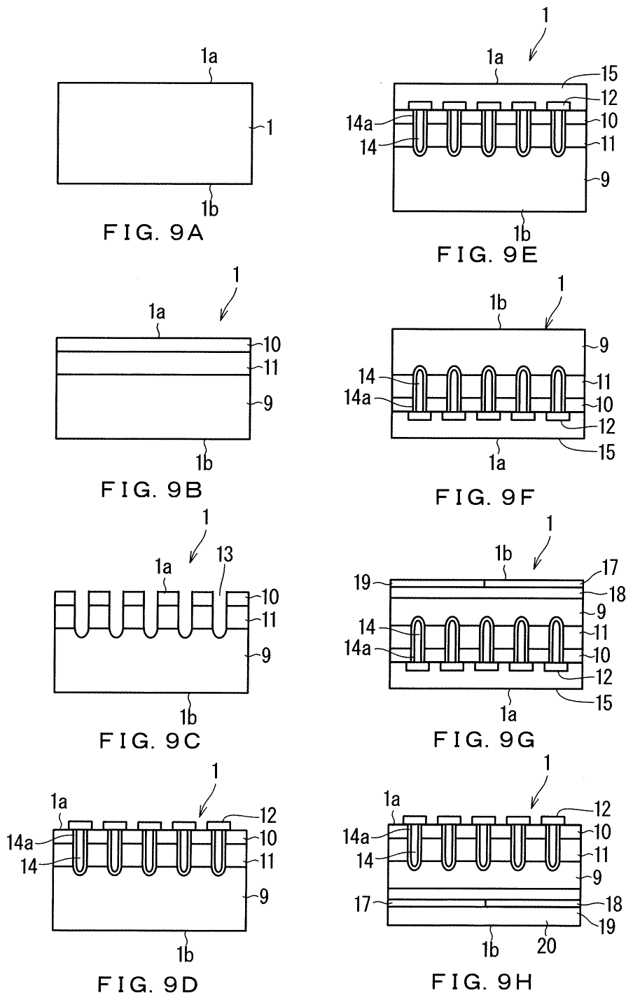

A method for manufacturing a semiconductor device includes a semiconductor substrate preparing step, a first main surface side semiconductor layer forming step, a first main surface side trench forming step, a first main surface side gate electrode forming step, a first main surface side protective film forming step, a second main surface side grinding step, a second main surface side impurity implantation step, a second main surface side laser annealing step, a second main surface side electrode forming step, a first main surface side protective film removing step, and a dicing step. FIGS. 9A to 9H are cross-sectional views schematically showing an example of a configuration of the semiconductor substrate 1 in each step. FIGS. 9A to 9H show a portion corresponding to one semiconductor element (RC-IGBT).

In the semiconductor substrate preparing step, an n-type semiconductor substrate 1 having a low donor concentration shown in FIG. 9A is prepared (step S1). Hereinafter, not only a state prepared in the semiconductor substrate preparing step but also a state in which various layers such as a semiconductor layer, an insulating layer, and an electrode are formed in the following manufacturing step will be referred to as a semiconductor substrate 1.

In the first main surface side semiconductor layer forming step, as shown in FIG. 9B, a p-type first main surface side p layer 10 and an n-type first main surface side n layer 11 are formed in a portion on the first main surface 1a side of the semiconductor substrate 1 (step S2). Specifically, impurities serving as donors and impurities serving as acceptors are sequentially ion-implanted into the first main surface 1a of the semiconductor substrate 1 so as to have different depths, and heating treatment is performed. Accordingly, a first main surface side p layer 10 and a first main surface side n layer 11 are formed. Hereinafter, in the semiconductor substrate 1 in FIG. 9B, a portion other than the first main surface side p layer 10 and the first main surface side n layer 11 is also referred to as a drift layer 9. The impurity concentration of the first main surface side p layer 10 and the n-type first main surface side n layer 11 is higher than the impurity concentration of the drift layer 9. For example, impurities such as arsenic and phosphorus are used as donors, and impurities such as boron and aluminum are used as acceptors. By selectively implanting donors and acceptors using a mask, a plurality of first main surface side p layers 10 and first main surface side n layers 11 corresponding to a plurality of semiconductor elements formed in the plane of the semiconductor substrate 1 are formed in the same pattern.

In the first main surface side trench forming step, as shown in FIG. 9C, a plurality of trenches (that is, grooves) 13 are formed on the first main surface 1a side of the semiconductor substrate 1 (step S3). Specifically, the first main surface side trench formation step includes a heating step, an exposure step, and an etching step. In the heating step, an oxide film is formed on the first main surface 1a side of the semiconductor substrate 1. In the exposure step, a shot pattern is formed on an oxide film using a photomask, and the oxide film is used as an etching mask having an opening. In the etching step, the first main surface 1a side of the semiconductor substrate 1 is etched using the etching mask and a trench 13 having a depth reaching the drift layer 9 is formed.

In the first main surface side gate electrode forming step, as shown in FIG. 9D, the oxide film 14a, the gate electrode 14, and the upper electrode 12 are formed (step S4). Specifically, the first main surface side gate electrode forming step includes a polysilicon deposition step, an etching step, and an electrode metal film forming step. Before the polysilicon deposition step, the semiconductor substrate 1 is heated in an atmosphere containing oxygen, and the oxide film 14a is formed on the inner wall of the trench 13. At that time, an oxide film is also formed on the first main surface 1a of the semiconductor substrate 1. In the polysilicon deposition step, polysilicon doped with n-type or p-type impurities by chemical vapor deposition (CVD) or the like is deposited in the trench 13 in which the oxide film 14a is formed on the inner wall, and the gate electrode 14 is formed in the trench 13. In the etching step, the oxide film formed on the first main surface 1a of the semiconductor substrate 1 is removed by etching. In the electrode metal film forming step, the upper electrode 12 to be connected to each gate electrode 14 is formed on the first main surface 1a side of the semiconductor substrate 1.

In the first main surface side protective film forming step, as shown in FIG. 9E, a protective film 15 for suppressing damage on the first main surface 1a side is formed (step S5). The material of the protective film 15 is desirably a tape or a polyimide-based material.

In the second main surface side grinding step, the first main surface 1a side of the semiconductor substrate 1 on which the protective film 15 is formed is sucked by a stage of a grinding apparatus, and the second main surface 1b of the semiconductor substrate 1 is ground so that the thickness of the semiconductor substrate 1 is 100 μm or less, for example (step S6). Accordingly, the semiconductor substrate 1 is thinned. Since a damaged layer remains in the surface layer on the second main surface 1b side of the semiconductor substrate 1 by the second main surface side grinding step, it is desirable to remove the damaged layer by the etching step. The semiconductor substrate 1 is brought into the state in FIG. 9F by the second main surface side grinding step.

In the second main surface side impurity implantation step, as shown in FIG. 9G, the respective impurity implantation layers serving as the n-type cathode layer 17, the n-type buffer layer 18, and the p-type collector layer 19 are formed (step S7). These respective impurity implantation layers become the cathode layer 17, the buffer layer 18, and the collector layer 19 by a second main surface side laser annealing step described below. The second main surface side impurity implantation step includes a lithography step and an ion implantation step. In the lithography step, a mask is formed on the second main surface 1b side of the semiconductor substrate 1. In the ion implantation step, impurities are implanted through the opening of the mask formed in the lithography step. Here, impurity implantation layers serving as the cathode layer 17, the buffer layer 18, and the collector layer 19 are formed by repeatedly performing the lithography step and the ion implantation step. In the ion implantation step, for example, impurities such as arsenic and phosphorus are used as donors, and impurities such as boron and aluminum are used as acceptors. The depth of the impurity implantation layer is, for example, about several μm. The impurity concentration of each of the impurity implantation layers corresponding to the cathode layer 17, the buffer layer 18, and the collector layer 19 is higher than the impurity concentration of the drift layer 9.

By performing the steps up to the second main surface side impurity implantation step, damage accumulates on the second main surface 1b side of the semiconductor substrate 1. Therefore, on the second main surface 1b side of the semiconductor substrate 1, a crack 1e of about several mm×several mm may occur in plan view.

In the second main surface side laser annealing step, the impurity implantation layer on the second main surface 1b side formed in the second main surface side impurity implantation step is electrically activated by laser annealing treatment (step S8). Accordingly, the cathode layer 17, the buffer layer 18, and the collector layer 19 are formed in a region at a depth of several μm on the second main surface 1b side of the semiconductor substrate 1.

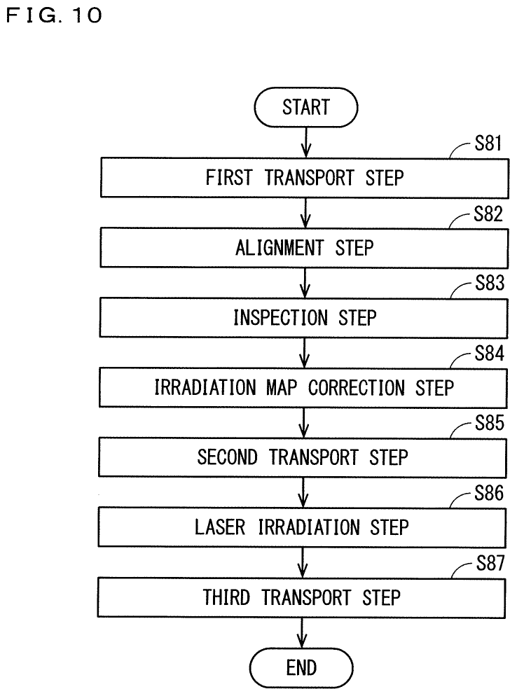

FIG. 10 is a flowchart showing a specific example of the second main surface side laser annealing step. As shown in FIG. 10, the second main surface side laser annealing step includes a first transport step, an alignment step, an inspection step, an irradiation map correction step, a second transport step, a laser irradiation step, and a third transport step.

In the first transport step, the transport unit 140 takes out one untreated semiconductor substrate 1 of the plurality of semiconductor substrates 1 stored in the cassette 38, and transports the semiconductor substrate 1 to the aligner 121 (step S81). The aligner 121 horizontally holds the carried-into semiconductor substrate 1.

In the alignment step, the aligner 121 rotates the semiconductor substrate 1 so that the notch 1d of the semiconductor substrate 1 is positioned at a specified rotational position (step S82).

In the inspection step, the sensor section 122 inspects the presence or absence of the crack 1e of the semiconductor substrate 1 (step S83). The sensor section 122 transmits an inspection result signal indicating the inspection result to the control unit 160. The inspection result signal includes, for example, information indicating the presence or absence of the crack 1e and the position and shape of the crack 1e on the semiconductor substrate 1.

It should be noted that in the example in FIG. 1, the inspection unit 120 includes the aligner 121 and the sensor section 122, but is not necessarily limited thereto. The inspection unit 120 only needs to include the sensor section 122. In addition, the inspection unit 120 may be provided outside the semiconductor manufacturing apparatus 100. In this case, before the semiconductor substrate 1 is carried into the semiconductor manufacturing apparatus 100, each semiconductor substrate 1 is inspected in the inspection unit 120.

In the irradiation map correction step, the inspection result receiving section 161 of the control unit 160 receives the inspection result signal from the inspection unit 120, and the irradiation map correction section 162 corrects the irradiation map information based on the inspection result signal (step S84). Specifically, when the inspection unit 120 does not detect the crack 1e, the irradiation map correction section 162 keeps the irradiation map information as it is. On the other hand, when the inspection unit 120 detects the crack 1e, the irradiation map correction section 162 corrects the irradiation map information based on the position and the shape of the crack 1e. Specifically, the irradiation map correction section 162 corrects the irradiation map information so that the time integral of the light amount of the beam 31 per unit area in the crack region 1f is smaller than the time integral of the light amount of the beam 31 per unit area in the region different from the crack region 1f. As a more specific example, the control unit 160 corrects the irradiation map information so that the beam 31 disappears in the crack region 1f.

Here, a description will be given with reference to the semiconductor substrate 1 in FIG. 7. In the example in FIG. 7, a pair of components 51A to a pair of components 51E constitute the crack region 1f. The pair of components 51A and the pair of components 51B are adjacent to each other in the scanning direction, and the pair of components 51C to the pair of components 51E are adjacent to each other in the scanning direction. The scanning line including the pair of components 51A and the pair of components 51B is adjacent in the pitch direction to the scanning line including from the pair of components 51C to the pair of components 51E. The component 51A is positioned upstream of the component 51B in the scanning line, the component 51B is positioned upstream of the component 51C in the scanning line, the component 51C is positioned upstream of the component 51D in the scanning line, and the component 51D is positioned upstream of the component 51E in the scanning line.

In this case, the irradiation map correction section 162 corrects the irradiation map information so that the beam 31 disappears in the crack region 1f including the pair of components 51A to the pair of components 51E. The host PC 150 rewrites the operation information on the laser opening and closing apparatus 134 based on the corrected irradiation map information so that the beam 31 disappears in the crack region 1f, and transfers the rewritten operation information to the control unit 160. In the rewritten operation information, the laser opening and closing apparatus 134 blocks the laser light 30 in a period in which the beam 31 passes through the crack region 1f.

As described above, the semiconductor manufacturing apparatus 100 collates the initial irradiation map information with the information indicating the position and shape of the crack 1e, and rewrites the operation information on the laser opening and closing apparatus 134.

In the second transport step, the transport unit 140 takes out the inspected semiconductor substrate 1 from the inspection unit 120 and transports the semiconductor substrate 1 to the laser annealing unit 130 (step S85). The stage 137 of the laser annealing unit 130 holds the carried-into semiconductor substrate 1 in an attitude in which the first main surface 1a faces the stage 137.

In the laser irradiation step, the annealing control section 163 controls the laser annealing unit 130 based on the operation information on the optical unit 131 and the scanning section 138 to perform the laser annealing treatment (step S86).

When the inspection unit 120 does not detect the crack 1e, the annealing control section 163 controls the optical unit 131 and the scanning section 138 based on the initial operation information to cause the beam 31 to sequentially move along all the scanning lines. Accordingly, the laser annealing treatment is performed on all the components 51, and the laser annealing treatment can be performed on the entire semiconductor substrate 1.

On the other hand, when the inspection unit 120 detects the crack 1e, the annealing control section 163 controls the optical unit 131 and the scanning section 138 based on the operation information rewritten based on the corrected irradiation map information. Here, the operation information on the laser opening and closing apparatus 134 is rewritten, and the operation information on the scanning section 138 remains as it is. Since the operation information on the scanning section 138 remains as it is, the scanning section 138 scans all the scanning lines with the beam 31.

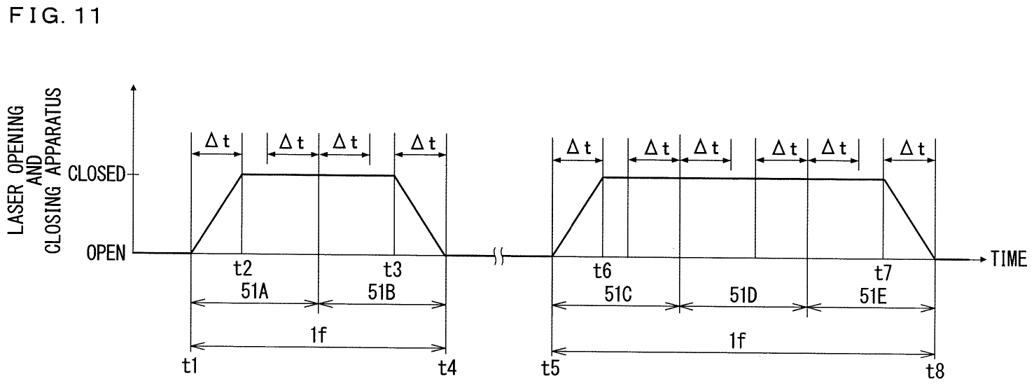

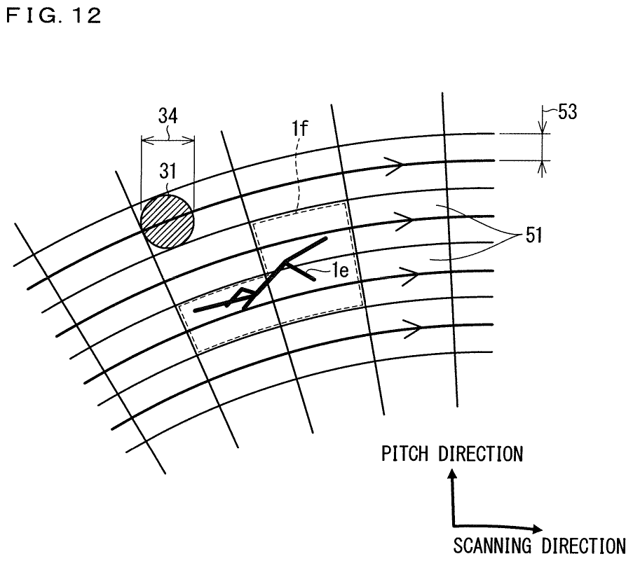

FIG. 11 is a diagram showing an example of a temporal change in the open/close state of the laser opening and closing apparatus 134 after rewriting. For example, the laser opening and closing apparatus 134 starts switching operation from the open state to the closed state at time point t1. The time point t1 is a time point when the end 31a of the beam 31 reaches the end 51a of the pair of components 51A. In the example in FIG. 11, the component 51 in which the beam 31 is positioned at each time point is also shown on the horizontal axis. In the example in FIG. 11, the laser opening and closing apparatus 134 completes the switching operation from the open state to the closed state at time point t2 at which the beam 31 is still positioned in the component 51A. In the example in FIG. 11, the open/close time Δt required for the switching operation is also shown. Then, in order that the switching operation from the closed state to the open state can be completed at the time point t4 at which the end 31b of the beam 31 reaches the end 51b of the pair of components 51B, the laser opening and closing apparatus 134 starts the switching operation from the closed state to the open state at the time point t3 being before the time point t4 by the opening/closing time Δt. Accordingly, the laser opening and closing apparatus 134 can block the laser light 30 in a period in which the beam 31 passes through the pair of components 51A and the pair of components 51B. Accordingly, the beam 31 substantially disappears in the pair of components 51A and the pair of components 51B. Therefore, the time integral of the light amount per unit area in the pair of components 51A and 51B can be reduced.

In the example in FIG. 11, the laser opening and closing apparatus 134 restarts switching operation from the open state to the closed state at time point t5. The time point t5 is a time point when the end 31b of the beam 31 reaches the end 51b of the pair of components 51C. In the example in FIG. 11, the laser opening and closing apparatus 134 completes the switching operation from the open state to the closed state at time point t6 at which the beam 31 is still positioned in the component 51C. Then, in order that the switching operation from the closed state to the open state can be completed at the time point t8 at which the end 31a of the beam 31 reaches the end 51a of the pair of components 51E, the laser opening and closing apparatus 134 starts the switching operation from the closed state to the open state at the time point t7 being before the time point t8 by the opening/closing time Δt. Accordingly, the time integral of the light amount per unit area in the pair of components 51C to the pair of components 51E can be reduced.

It should be noted that in this specific example, since the irradiation of the crack region 1f with the laser light 30 is substantially avoided, it can be said that the crack region 1f is a laser irradiation avoidance region.

As described above, the laser opening and closing apparatus 134 is in the closed state during the period in which the beam 31 passes through the crack region 1f. Conversely, the laser opening and closing apparatus 134 is in the open state in a period other than the period in which the beam 31 passes through the crack region 1f. Therefore, the time integral of the light amount of the beam 31 with which a unit area in the crack region 1f is irradiated is smaller than the time integral of the light amount of the laser light 30 with which a unit area in the region other than the crack region 1f is irradiated.

For comparison, a case where the crack 1e is also irradiated with the laser light with a sufficient light amount will be described. In this case, the laser light 30 propagates through the internal space of the crack 1e and reaches the first main surface 1a of the semiconductor substrate 1. That is, since there is no member that absorbs the laser light 30 in the internal space of the crack 1e, the first main surface 1a side of the semiconductor substrate 1 is irradiated with the laser light 30 with a large light amount. Therefore, the laser light 30 is absorbed by the semiconductor substrate 1 on the first main surface 1a side, and the semiconductor substrate 1 is heated also on the first main surface 1a side. When the crack 1e penetrates the semiconductor substrate 1, the laser light 30 can reach also the stage 127 by passing through the internal space of the crack 1e. In this case, the stage 137 is also heated. When the semiconductor substrate 1 is heated on the first main surface 1a side or the stage 137 is also heated as described above, adhesion may occur between the semiconductor substrate 1 and the stage 137. In this case, even if the semiconductor device region 1c in which the crack 1e is not formed is present, it is necessary to discard the entire semiconductor substrate 1. Furthermore, the stage 137 itself may also need to be replaced.

On the other hand, in the present preferred embodiment, since it is possible to reduce the time integral of the light amount of the laser light 30 applied to the crack 1e, it is possible to suppress unnecessary heating in the crack 1e as described above. Therefore, it is possible to appropriately perform the laser annealing treatment on the semiconductor device region 1c where the crack 1e is not formed while eliminating the above-described problem due to unnecessary heating in the region where the crack 1e has occurred. Therefore, in the semiconductor device region 1c where the crack 1e is not formed, the respective impurity implantation layers become the n-type cathode layer 17, the n-type buffer layer 18, and the p-type collector layer 19 (see FIG. 9G).

In the third transport step, the stage 137 releases the holding of the semiconductor substrate 1, and the transport unit 140 takes out the semiconductor substrate 1 from the laser annealing unit 130 and transports the semiconductor substrate 1 to the cassette 38 (step S87).

Returning to FIG. 8, in the second main surface side electrode forming step, as shown in FIG. 9H, the electrode 20 is formed on the second main surface 1b side of the semiconductor substrate 1 (step S9). The electrode 20 is film-formed by, for example, a sputtering apparatus. The material of the electrode 20 is, for example, aluminum.

In the first main surface side protective film removing step, as shown in FIG. 9H, the protective film 15 on the first main surface 1a side of the semiconductor substrate 1 is removed (step S10). For example, the protective film 15 is removed by chemical treatment.

In the dicing step, the semiconductor substrate 1 is divided into each of the semiconductor device regions 1c (that is, the manufactured semiconductor device) (step S11).

Through the above steps, a semiconductor element (for example, RC-IGBT) as a semiconductor device is obtained. However, the semiconductor device to be manufactured by the method for manufacturing a semiconductor device of the present preferred embodiment may be a semiconductor module in which a semiconductor element is provided with, for example, a wire and sealed with a sealing resin, or may be an apparatus in which the semiconductor module is further incorporated.

As described above, in the present preferred embodiment, in the laser irradiation step (step S86), the laser light 30 is scanned on the second main surface 1b of the semiconductor substrate 1 so that the time integral of the light amount of the laser light 30 with which the unit area in the crack region 1f including the crack 1e is irradiated is smaller than the time integral of the light amount of the laser light 30 with which the unit area in a region different from the crack region 1f is irradiated, and the laser annealing treatment is performed on the semiconductor substrate 1. Therefore, it is possible to perform the laser annealing treatment on the region other than the crack 1e of the semiconductor substrate 1 while avoiding the problem caused by unnecessary heating to the crack 1e. Therefore, a semiconductor device can be manufactured in the semiconductor device region 1c where the crack 1e does not occur, and a decrease in yield can be suppressed.

In a more specific example, in the laser irradiation step (step S86), the second main surface 1b of the semiconductor substrate 1 is scanned with the laser light 30 while the irradiation of the crack region 1f with the laser light 30 is avoided by synchronizing the switching operation of the laser opening and closing apparatus 134 and the scanning by the scanning section 138, and the laser annealing treatment is performed. Therefore, even in the scanning line including the crack region 1f, a region other than the crack region 1f is irradiated with the laser light 30. Therefore, a relatively wide region can be irradiated with the laser light 30, and the impurity implantation layer can be activated in a relatively wide region. Accordingly, a decrease in yield due to the crack 1e can be substantially minimized.

It should be noted that in the above example, in the laser irradiation step (step S86), the scanning section 138 causes scans the beam 31 to scan along the linear scanning direction. However, the present disclosure is not necessarily limited thereto. FIG. 12 is an enlarged view showing another example of the irradiation map according to the first preferred embodiment. In the example in FIG. 12, a circular beam 31 is also shown, and the beam 31 moves on the semiconductor substrate 1 with the circumferential direction along the circumferential edge of the semiconductor substrate 1 as the scanning direction and the radial direction of the semiconductor substrate 1 as the pitch direction. In this case, the scanning section 138 includes a rotation mechanism that rotates the stage 137 about a vertical rotation axis line passing through the center of the semiconductor substrate 1, and a moving mechanism that moves the rotation mechanism along the pitch direction.

In the example in FIG. 12, each component 51 has a strip shape extending along the circumferential direction, and the plurality of components 51 are arranged in a matrix with the scanning direction as the row direction and the pitch direction as the column direction. In the example in FIG. 12, the width 53 of the component 51 is set to one-half of the diameter 34 of the beam 31. That is, also in the example in FIG. 12, the components 51 for two rows constitute one scanning line. By the scanning section 138 rotating the stage 137, the beam 31 moves along the circumferential direction (that is, the scanning direction), and the scanning line is scanned. In addition, by the scanning section 138 moving the stage 137 in the pitch direction, the beam 31 moves along the pitch direction, and the beam 31 can be positioned on the next scanning line. The rotation mechanism of the scanning section 138 rotates the stage 137 so that the linear velocity of the semiconductor substrate 1 in each scanning line, that is, the moving velocity of the beam 31 becomes constant.

Even in this case, when the inspection unit 120 detects the crack 1e, the irradiation map correction section 162 corrects the irradiation map information so that the time integral of the light amount per unit area in the crack region 1f is smaller than the time integral of the light amount per unit area in a region different from the crack region 1f. For example, the irradiation map correction section 162 corrects the irradiation map information so that the laser opening and closing apparatus 134 blocks the laser light 30 in a period in which the beam 31 passes through the crack region 1f.

### Second Preferred Embodiment

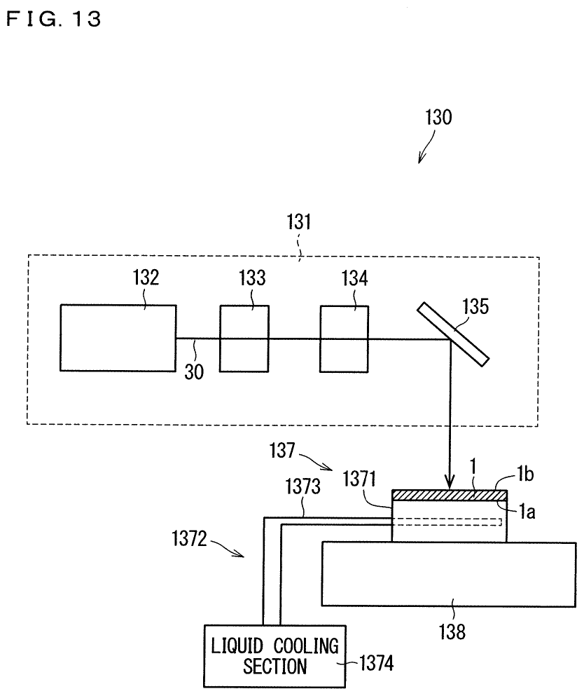

An example of a configuration of the semiconductor manufacturing apparatus 100 according to the second preferred embodiment is similar to the configuration in FIG. 1. However, the second preferred embodiment is different from the first preferred embodiment in the configuration of the laser annealing unit 130. FIG. 13 is a side view showing an example of a configuration of the laser annealing unit 130 according to the second preferred embodiment. In the second preferred embodiment, the stage 137 of the laser annealing unit 130 has a function of cooling the semiconductor substrate 1. The stage 137 includes, for example, a cooling stage 1371 made of metal and a cooling mechanism 1372 that cools the cooling stage 1371.

The cooling stage 1371 is formed of a metal having high thermal conductivity, and has a placement surface in contact with the first main surface 1a of the semiconductor substrate 1. The cooling stage 1371 is, for example, a suction stage.

The cooling mechanism 1372 includes, for example, a coolant supply path 1373 and a liquid cooling section 1374. The coolant supply path 1373 mainly includes a pipe. A part of the coolant supply path 1373 is routed inside the cooling stage 1371, and an upstream end and a downstream end thereof are connected to the liquid cooling section 1374. The liquid cooling section 1374 cools a coolant such as water supplied from the downstream end of the coolant supply path 1373, and supplies the cooled coolant to the upstream end of the coolant supply path 1373. The coolant flows through the coolant supply path 1373 and cools the cooling stage 1371 inside the cooling stage 1371. Since the cooling stage 1371 is cooled, the first main surface 1a of the semiconductor substrate 1 sucked to the cooling stage 1371 is also cooled.

The operation of the semiconductor manufacturing apparatus 100 according to the second preferred embodiment is similar to that of the first preferred embodiment. However, the stage 137 cools the first main surface 1a of the semiconductor substrate 1 at least in the laser irradiation step (step S86). That is, when the laser annealing treatment is performed, the cooling stage 1371 cools the first main surface 1a of the semiconductor substrate 1 while supporting the first main surface 1a. Therefore, in the laser irradiation step, while it is possible to activate the impurity implantation layer by heating the second main surface 1b side of the semiconductor substrate 1, it is possible to suppress the temperature rise on the first main surface 1a side by cooling the first main surface 1a side of the semiconductor substrate 1.

Moreover, also in the second preferred embodiment, the time integral of the light amount per unit area is small near the crack 1e. Conversely, the laser light 30 is not directly incident on the cooling stage 1371 with a large light amount. Therefore, even if the metallic cooling stage 1371 is adopted, it is possible to suppress mixing (what is called contamination) of impurities from the metallic cooling stage 1371 to the semiconductor substrate 1 due to laser irradiation.

As described above, according to the second preferred embodiment, it is possible to achieve both suppression of heat transfer to the first main surface 1a side of the semiconductor substrate 1 and activation of impurities in a region at a depth of about several μm of the ultra-thin semiconductor substrate 1.

### Third Preferred Embodiment

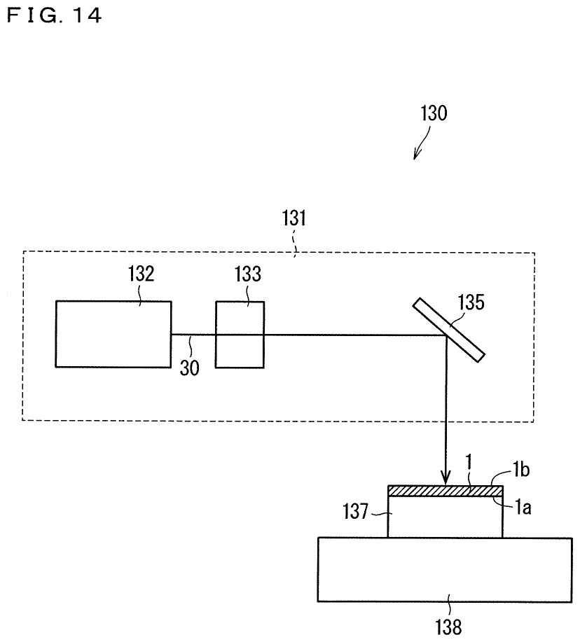

An example of a configuration of the semiconductor manufacturing apparatus 100 according to the third preferred embodiment is similar to the configuration in FIG. 1. However, the third preferred embodiment may be different from the first preferred embodiment in the configuration of the laser annealing unit 130. FIG. 14 is a side view showing an example of a configuration of the laser annealing unit 130 according to the third preferred embodiment. In the third preferred embodiment, the laser annealing unit 130 does not need to include the laser opening and closing apparatus 134 in the first preferred embodiment.

The operation of the semiconductor manufacturing apparatus 100 according to the third preferred embodiment is similar to that of the first preferred embodiment. However, in the third preferred embodiment, in the laser irradiation step (step S86), with the scanning line including the crack 1e avoided, the second main surface 1b of the semiconductor substrate 1 is scanned with the laser light 30, and the laser annealing treatment is performed. Hereinafter, a specific description will be given.

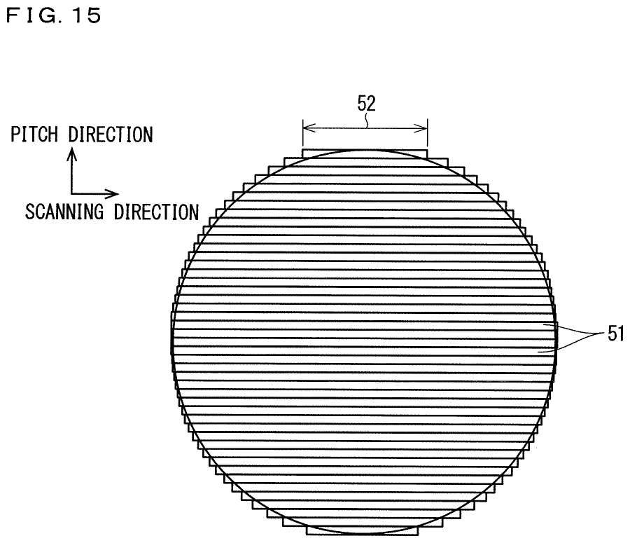

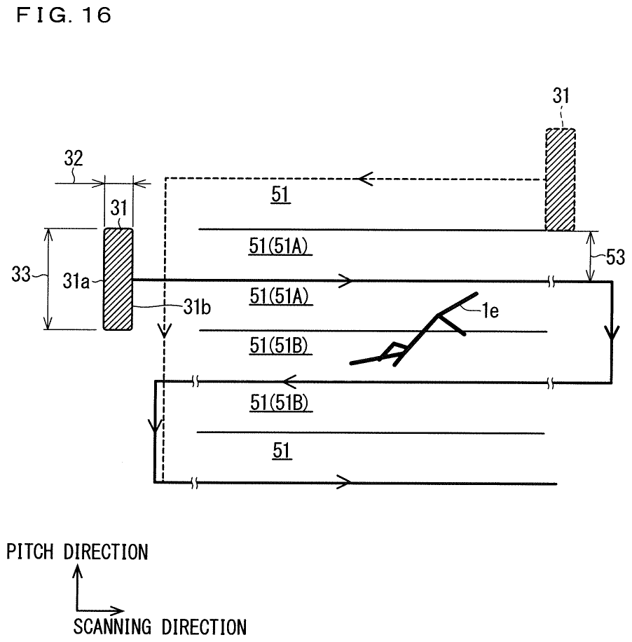

FIG. 15 is a diagram for illustrating the irradiation map according to the third preferred embodiment. In the irradiation map according to the third preferred embodiment, each component 51 has a rectangular shape long in the scanning direction, and the plurality of components 51 are one-dimensionally side by side and adjacent to each other in the pitch direction. FIG. 16 is an enlarged view of a part of the irradiation map in FIG. 15. The width 53 of the component 51 is set based on the beam width 33 of the beam 31 as in the first preferred embodiment. As a specific example, the width 53 of the component 51 is set to one-half of the beam width 33. In this case, the beam 31 moves along the scanning direction, whereby the components 51 for two rows are irradiated with the beam 31. That is, one scanning line includes components 51 for two rows.

As shown in FIG. 15, the width 52 of each component 51 is set to be shorter as it goes away from the central portion of the semiconductor substrate 1. That is, the width 52 of the component 51 positioned uppermost and the width 52 of the component 51 positioned lowermost are the shortest.

Initially, the irradiation map is set so that all the components 51 are irradiated with the beam 31 with a specified light amount. Therefore, in the scanning control based on the initial irradiation map information, the operation information on the optical unit 131 and the scanning section 138 is determined so that all the components 51 are irradiated with the beam 31 with a specified light amount. For example, the operation information is determined so that the laser opening and closing apparatus 134 always keeps the open state during scanning of the laser light 30 and the scanning section 138 causes the beam 31 to pass through all the components 51 (that is, all scanning lines).

When the inspection unit 120 does not detect the crack 1e, the irradiation map correction section 162 adopts the initial irradiation map as it is (step S84), so that all the components 51 are irradiated with the beam 31 (step S86).

On the other hand, when the inspection unit 120 detects the crack 1e, the irradiation map correction section 162 corrects the irradiation map information so that the time integral of the light amount in the crack region including the crack 1e is smaller than the time integral of the light amount in a region different from the crack region. As a specific example, the irradiation map correction section 162 corrects the irradiation map so that the beam 31 scans the semiconductor substrate 1 while avoiding the scanning line including the crack 1e (hereinafter, referred to as an avoidance line). In the example in FIG. 16, the pair of components 51A and the pair of components 51B correspond to avoidance lines.

Then, the host PC 150 rewrites the operation information on the scanning section 138 based on the corrected irradiation map information so as to perform scanning while skipping the entire avoidance line, and transfers the rewritten operation information to the control unit 160. For example, the host PC 150 causes the beam 31 to avoid the scanning of the avoidance line by rewriting the moving speed (hereinafter, referred to as a pitch speed.) of the beam 31 in the pitch direction included in the operation information. It should be noted that the pitch speed is a speed at which the beam 31 moves in the pitch direction on the outer circumferential side of the semiconductor substrate 1.

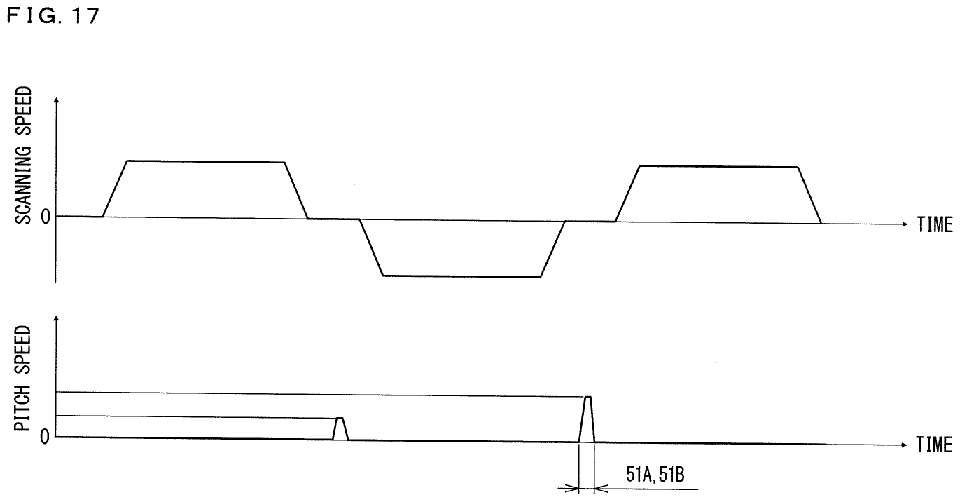

FIG. 17 is a graph showing an example of the temporal change in the moving speed in the scanning direction (hereinafter, referred to as a scanning speed), and the pitch speed, of the beam 31. In the example in FIG. 17, the pitch speed immediately before the avoidance line is set to be higher than the pitch speed in the other scanning lines. In the example in FIG. 17, periods during which the beam 31 moves along the pitch direction so as to skip the avoidance lines (that is, the pair of components 51A and the pair of components 51B) are denoted by reference numerals 51A, 51B.

As described above, the host PC 150 rewrites the operation information of the scanning section 138 so that the movement amount in the pitch direction corresponding to the avoidance line becomes larger than the movement amount in the pitch direction corresponding to the other scanning lines.

In the laser irradiation step (step S86), since the annealing control section 163 controls the scanning section 138 based on the operation information after rewriting, the beam 31 moves on the second main surface 1b of the semiconductor substrate 1 while avoiding the avoidance line including the crack 1e. Therefore, the amount of heat applied to the crack 1e can be reduced. Therefore, as in the first preferred embodiment, it is possible to perform the laser annealing treatment on the region other than the crack 1e of the semiconductor substrate 1 while suppressing the problem caused by unnecessary heating to the crack 1e.

Moreover, according to the semiconductor manufacturing apparatus 100 according to the third preferred embodiment, it is not necessary to cause the laser opening and closing apparatus 134 to perform a switching operation in the crack region 1f, and thus control is easy. In addition, when the laser opening and closing apparatus 134 is not provided, it is possible to reduce the cost of the semiconductor manufacturing apparatus 100.

In addition, in the above specific example, the pitch speed at the time of crossing the avoidance line is increased. According to this, the throughput of the laser annealing treatment can be improved.

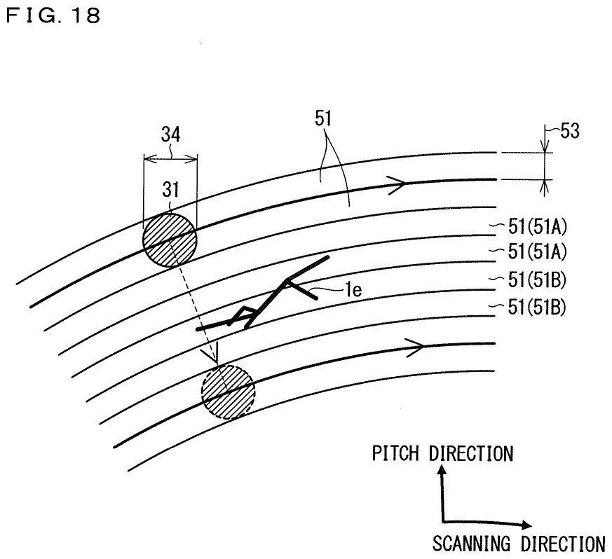

It should be noted that in the above example, although the scanning direction is the linear direction, the scanning direction may be the circumferential direction along the circumferential edge of the semiconductor substrate 1 as in the first preferred embodiment. FIG. 18 is an enlarged view showing another example of the irradiation map according to the third preferred embodiment. In the example in FIG. 18, each component 51 has an annular shape extending along the circumferential direction, and the plurality of components 51 are concentrically arranged adjacent to each other in the radial direction (pitch direction).

In the example in FIG. 18, the width 53 of the component 51 is set to one-half of the diameter 34 of the beam 31. That is, also in the example in FIG. 18, the components 51 for two rows constitute one scanning line.

Even in this case, when the inspection unit 120 detects the crack 1e, the irradiation map correction section 162 corrects the irradiation map so that the beam 31 scans the semiconductor substrate 1 while avoiding the avoidance line including the crack 1e. In FIG. 18, the avoidance lines are scanning lines for two rows including a pair of components 51A and a pair of components 51B. Then, the host PC 150 rewrites the operation information on the scanning section 138 based on the corrected irradiation map information so as to perform scanning while skipping the entire avoidance line, and transfers the rewritten operation information to the control unit 160. For example, as shown in FIG. 17, the host PC 150 rewrites the pitch speed of the beam 31 in the pitch direction included in the operation information. Accordingly, the beam 31 moves on the second main surface 1b of the semiconductor substrate 1 while avoiding the avoidance line including the crack 1e. Therefore, the amount of heat applied to the crack 1e can be reduced.

It should be noted that each preferred embodiment can be freely combined, and each preferred embodiment can be appropriately modified or omitted.

Hereinafter, various aspects of the present disclosure will be collectively described as supplementary notes.

(Supplementary Note 1)

A method for manufacturing a semiconductor device, the method including:
detecting a crack generated on a main surface of a substrate; and
scanning the main surface of the substrate with the laser light in order that a time integral of a light amount of laser light for annealing with which a unit area in a crack region including the detected crack is irradiated is smaller than a time integral of a light amount of the laser light with which a unit area in a region different from the crack region is irradiated, to perform laser annealing treatment on the substrate.

(Supplementary Note 2)

The method for manufacturing a semiconductor device according to Supplementary note 1, wherein when the laser annealing treatment is performed, a cooling stage made of metal cools a first main surface on an opposite side from the main surface of the substrate while supporting the first main surface.

(Supplementary Note 3)

The method for manufacturing a semiconductor device according to Supplementary note 1 or 2, wherein
a switching operation of a laser opening and closing apparatus that switches passage and blocking of the laser light synchronizes with scanning of the laser light by a scanning section in order that the main surface of the substrate is scanned with the laser light while avoiding irradiation of the crack region with the laser light to perform the laser annealing treatment.

(Supplementary Note 4)

The method for manufacturing a semiconductor device according to Supplementary note 1 or 2, wherein
a movement amount in a pitch direction orthogonal to a scanning direction along a scanning line is increased in order that the main surface of the substrate is scanned with the laser light while avoiding an avoidance line being a scanning line including the crack to perform the laser annealing treatment.

(Supplementary Note 5)

The method for manufacturing a semiconductor device according to any one of Supplementary notes 1 to 4, further including grinding and thinning the substrate before performing the laser annealing treatment.

(Supplementary note 6)

A semiconductor manufacturing apparatus including:
an inspection unit configured to detect a crack generated on a main surface of a substrate;
a stage configured to hold the substrate;
an optical unit configured to irradiate the substrate held by the stage with laser light for annealing;
a scanning section configured to scan the substrate with the laser light; and
a control unit configured to control the optical unit and the scanning section so that the main surface of the substrate is scanned with the laser light in order that a time integral of a light amount of the laser light with which a unit area in a crack region including the crack detected by the inspection unit is irradiated is smaller than a time integral of a light amount of the laser light with which a unit area in a region different from the crack region is irradiated, scan the main surface of the substrate with the laser light to perform laser annealing treatment on the substrate.

While the disclosure has been shown and described in detail, the foregoing description is in all aspects illustrative and not restrictive. It is therefore understood that numerous modifications and variations can be devised.

What is claimed is:

1. A method for manufacturing a semiconductor device, the method comprising:
detecting a crack generated on a main surface of a substrate; and
scanning the main surface of the substrate with the laser light in order that a time integral of a light amount of laser light for annealing with which a unit area in a crack region including the detected crack is irradiated is smaller than a time integral of a light amount of the laser light with which a unit area in a region different from the crack region is irradiated, to perform laser annealing treatment on the substrate.

2. The method for manufacturing a semiconductor device according to claim 1, wherein when the laser annealing treatment is performed, a cooling stage made of metal cools a first main surface on an opposite side from the main surface of the substrate while supporting the first main surface.

3. The method for manufacturing a semiconductor device according to claim 1, wherein
a switching operation of a laser opening and closing apparatus that switches passage and blocking of the laser light synchronizes with scanning of the laser light by a scanning section in order that the main surface of the substrate is scanned with the laser light while avoiding irradiation of the crack region with the laser light to perform the laser annealing treatment.

4. The method for manufacturing a semiconductor device according to claim 2, wherein
a switching operation of a laser opening and closing apparatus that switches passage and blocking of the laser light synchronizes with scanning of the laser light by a scanning section in order that the main surface of the substrate is scanned with the laser light while avoiding irradiation of the crack region with the laser light to perform the laser annealing treatment.

5. The method for manufacturing a semiconductor device according to claim 1, wherein
a movement amount in a pitch direction orthogonal to a scanning direction along a scanning line is increased in order that the main surface of the substrate is scanned with the laser light while avoiding an avoidance line being a scanning line including the crack to perform the laser annealing treatment.

6. The method for manufacturing a semiconductor device according to claim 2, wherein
a movement amount in a pitch direction orthogonal to a scanning direction along a scanning line is increased in order that the main surface of the substrate is scanned with the laser light while avoiding an avoidance line being a scanning line including the crack to perform the laser annealing treatment.

7. The method for manufacturing a semiconductor device according to claim 1, further comprising grinding and thinning the substrate before performing the laser annealing treatment.

8. The method for manufacturing a semiconductor device according to claim 2, further comprising grinding and thinning the substrate before performing the laser annealing treatment.

9. A semiconductor manufacturing apparatus comprising:
an inspection unit configured to detecting a crack generated on a main surface of a substrate;
a stage configured to hold the substrate;
an optical unit configured to irradiate the substrate held by the stage with laser light for annealing;
a scanning section configured to scan the substrate with the laser light; and
a control unit configured to control the optical unit and the scanning section so that the main surface of the substrate is scanned with the laser light in order that a time integral of a light amount of the laser light with which a unit area in a crack region including the crack detected by the inspection unit is irradiated is smaller than a time integral of a light amount of the laser light with which a unit area in a region different from the crack region is irradiated, to perform laser annealing treatment on the substrate.
